(19) United States
(12) Patent Application Publication
(10) Pub. No.: US 2002/0070766 A1
(43) Pub. Date: Jun. 13, 2002

(54) Signal detection scheme for data communication links

(76) Inventors: Stefano G. Therisod, Sunnyvale, CA (US); Jae Joon Chang, San Jose, CA (US); Myunghee Lee, San Jose, CA (US)

Correspondence Address: AGILENT TECHNOLOGIES, Legal Department, 51U-PD, Intellectual Property Administration, P.O. Box 58043, Santa Clara, CA, 95052-8043, US

(21) Appl. No.: 09/734,794

(22) Filed: Dec. 11, 2000

(51) Int. Cl. H03K 5/153

(52) U.S. Cl. 327/74

(57) ABSTRACT

The present invention is a signal detect (SD)/loss-of-signal (LOS) circuit that is able to discern between received Signal and Noise in Digital Amplitude Modulated transmission systems. A window detector, having a low and high voltage limit, receives an input signal. A low pass filter having an output connects to the window detector. A differential comparator compares the output of the low pass filter at a negative input and a threshold voltage signal to generate an output signal indicative of the average power of the input signal.

### FIELD OF THE INVENTION

The invention is directed towards the field of signal detection, particularly towards signal detection circuits that differentiate between signal and noise.

### BACKGROUND

In data telecommunication systems, when sending data from a transmitter to a receiver, the ability to discern, at the receiver end of the link, between meaningful data and unwanted noise is mandatory. The ratio between the data received power and the power associated to the interfering signals is defined as the Signal to Noise ratio (S/N) and provides a useful way to quantify the quality of the data link. The Rx control signal usually provided to monitor the data transmission quality is the Signal Detect (SD) or Loss Of Signal (LOS). Its main function is to inform the link user when the signal is missing or when the S/N is low and consequently the received data aren't reliable.

There are several reasons for a low S/N. First, the received signal power is low. The physical medium over which the data are transmitted is interrupted, e.g. a broken optical fiber or broken wire. The signal is greatly attenuated or dispersed by the medium where it propagates, e.g. long distances between transmitter an receiver, faulty or dirty connectors, thunderstorms or heavy rains between radio stations. Second, the noise power at the receiver is high. In this situation, the receiver at low input power is unstable and oscillates. Alternatively, the receiver thermal noise is high. Due to cross-talk, the receiver detect power associated with signals transmitted on neighboring channels. Consequently, to be effective and reliable, the SD/LOS circuitry needs to discern between Noise and Signal Power and provide the correct answer.

The actually employed SD/LOS circuits, such as U.S. Pat. No. 5,381,052, “Peak detector circuit and application in a fiber optic receiver” disclosed by Kolte, issued Jan. 10, 1995, detect the sum Signal+Noise (S+N) power of the received input and rely on the assumption that the noise power is well below the signal power under all the operating conditions of the link. However, this is a very difficult condition to meet and not always can be achieved. Particularly, U.S. Pat. No. 5,381,052 teaches using single mode path of received signal led to single mode operation of signal detection.

### SUMMARY

The present invention is a signal detect (SD)/loss-of-signal (LOS) circuit that is able to discern between received Signal and Noise in Digital Amplitude Modulated transmission systems. A window detector, having a low and high voltage limit, receives an input signal. A low pass filter having an output connects to the window detector. A differential comparator compares the output of the low pass filter at a negative input and a threshold voltage signal to generate an output signal indicative of the average power of the input signal.

### BRIEF DESCRIPTION OF THE DRAWINGS

FIG. 1 illustrates the Probability Distribution Function when the voltage low is between VL and VH.

FIG. 2 illustrates as the Probability Distribution Function increasing between VL and VH when the S/N is low.

FIG. 3 illustrates the Probability Distribution Function having its maximum between VL and VH.

FIG. 4 illustrates a functional block diagram corresponding to the present invention.

FIG. 5 illustrates the simulation results corresponding to the functional block diagram shown in FIG. 4.

FIG. 6 illustrates a circuit schematic diagram corresponding to the functional block diagram shown in FIG. 4.

### DETAILED DESCRIPTION

Cross-coupling/Cross-talk problem is expected in using previous solution listed in U.S. Pat. No. 5,381,052 for the signal detection. Especially when using multiple data channels, cross coupling is a problem that cannot be ignored in a signal path in the receiver at each channel. In addition to the cross-coupled noise, intrinsic noise can incur the voltage difference between the absolute value of detected peak and the reference to lead to the failure of signal detector operation since it asserts at the time when it's not supposed to do so.

When the receiver is generating output due to the oscillation of the receiver, the methods of signal detection circuits in prior inventions are not able to discern the state of oscillation and the state of meaningful data. But, this new proposed invention can tell the difference between these two states. Besides, using a single signal path, which was disclosed in U.S. Pat. No. 5,381,052 can incur discharging problem of capacitor for peak holding circuit and this problem can lead to the malfunction of signal detection when there is long stream of identical consecutive signals. However, the method in this invention uses differential balanced signals to integrate the power in the region of de-assert level reducing the risk of discharging of capacitor which is a main source of signal detector malfunctioning. This concept can be extended to a single or any combination of multiple channel data receiver.

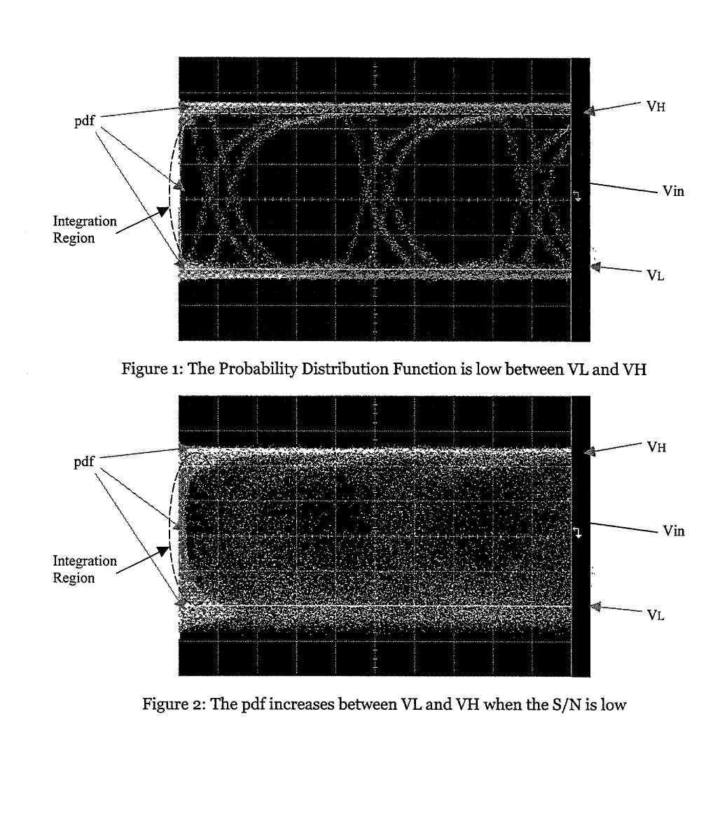

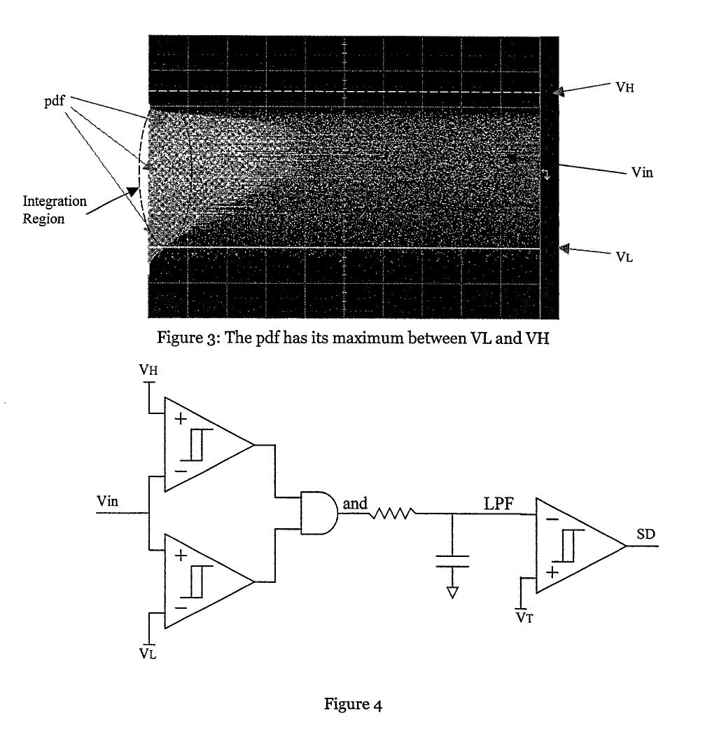

Provided that the probability distribution function (pdf) of the instantaneous amplitude value of a digital signal with high S/N reaches its minimum for amplitude values around the average power of the detected signals. (Most of the time the incoming data is at the logic level zero or one and only occasionally between those two values). Integrating the normalized pdf around the average power level leads to a result that is close to zero as shown in FIG. 1. On the contrary, when noise (in FIG. 3), or signals with low S/N (in FIG. 2) are detected, the normalized integrated pdf around the average power is well above zero. (Most of the time the incoming data is between the logic levels).

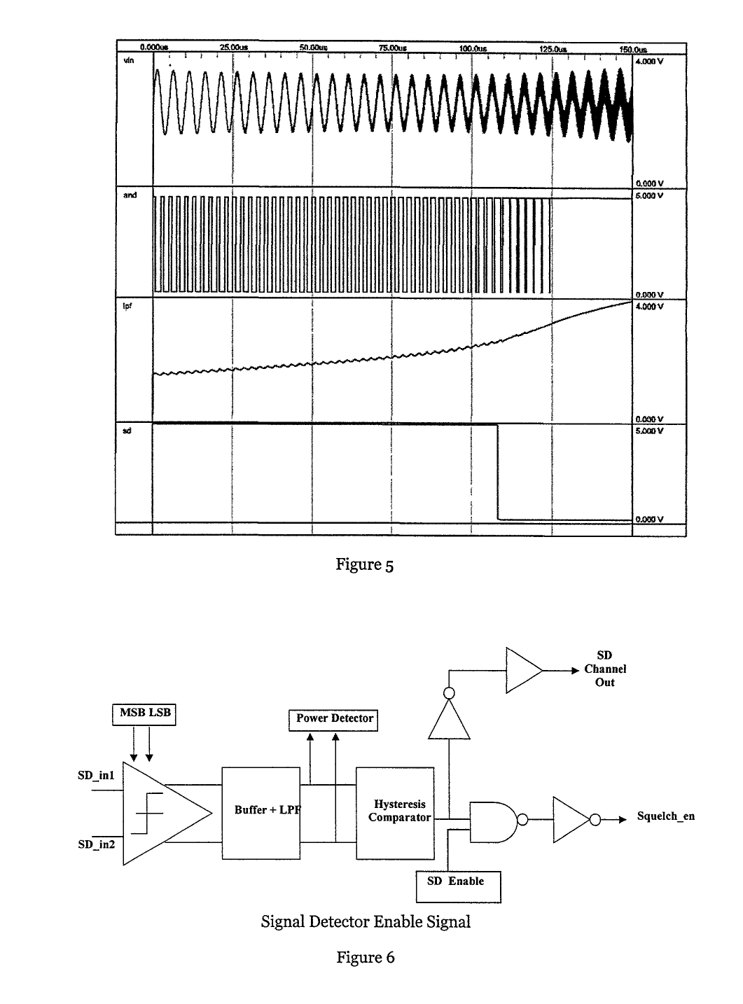

FIG. 4 illustrates a functional block diagram corresponding to the present invention, a differential SD/LOS circuitry able to discern between received Signal and Noise in Digital Amplitude Modulated transmission systems while, in FIG. 5, the results obtained from its simulation is shown. Even if the input signal has a constant amplitude peak to peak, when its S/N decrease below a certain threshold, the SD/LOS signal is de-asserted.

The differential loss-of-signal includes a window detector 13 comprising a low and high comparator 13A, 13B. The low comparator 13A compares the input voltage and the low voltage limit. The high comparator 13B compares the input voltage and the high voltage limit. An optional logical AND gate 14 combines the output of the low and high comparators 13A, 13B. A low-pass filter 15 receives the output of the window detector 13. Within the low-pass filter 15, a resistor 15A at one end receives the output of the window detector 13. Next, a capacitor 15B interposes the resistor 15A and ground. A differential comparator 17, connected to the low pass filter 15 at a negative input, receiving a third threshold voltage signal, provides an output signal indicative of the average power of the input signal.

FIG. 6 is a circuit schematic corresponding to the functional block diagram shown in FIG. 4. A window detector 13 receives two inputs and has two control inputs, most significant bit (MSB) and least significant bit (LSB). The LSB and MSB inputs correspond to the high and low voltage limits. The output of the window detector is received by a buffer and a low pass filter 15. A hysteresis comparator 17 receives as inputs the output of the buffer and low pass filter 15 and a voltage threshold signal. The output signal of the hysteresis comparator 17 is indicative of the average power of the input signal.

We claim:

1. A differential loss-of-signal circuit comprising:
a window detector having a low and high voltage limit, receiving an input signal;
a low pass filter having an output, connected to the window detector; and
a differential comparator, output of the low pass filter at a negative input, receiving a threshold voltage signal, providing an output signal indicative of the average power of the input signal.

2. A differential loss-of-signal circuit, as defined in claim 1, the window detector further comprising:
a high comparator, having an output, receiving the input signal and the high voltage limit; and
a low comparator, having an output, receiving the input signal and a low voltage limit.

3. A differential loss-of-signal circuit, as defined in claim 2, the low pass filter further comprising:
a resistor, connected to the window detector; and
a capacitor, connected between the resistor and ground.

4. A differential loss-of-signal circuit, as defined in claim 1, further comprising a logical AND gate interposing the window detector and the low pass filter.

5. A differential loss-of-signal circuit, as defined in claim 4, the window detector further comprising:
a high comparator, having an output, receiving the input signal and the high voltage limit; and
a low comparator, having an output, receiving the input signal and a low voltage limit.

6. A differential loss-of-signal circuit, as defined in claim 2, the low pass filter further comprising:
a resistor, connected to the window detector; and
a capacitor, connected between the resistor and ground.
